(19) United States
(12) Patent Application Publication
(10) Pub. No.: US 2024/0319281 A1
(43) Pub. Date: Sep. 26, 2024

(54) DETECTING RECHARGEABLE BATTERY SUPPLIER CELL BASED ON MEASURING CHARGE/DISCHARGE DV/DT

(71) Applicant: Continental Automotive Systems, Inc., Auburn Hills, MI (US)

(72) Inventors: Marcin Klimecki, Deer Park, IL (US); Vernon Cole, Deer Park, IL (US)

(73) Assignee: Continental Automotive Systems, Inc., Auburn Hills, MI (US)

(21) Appl. No.: 18/613,635

(22) Filed: Mar. 22, 2024

Related U.S. Application Data
(60) Provisional application No. 63/453,968, filed on Mar. 22, 2023.

(51) Int. Cl. G01R 31/374; H02J 7/00

(52) U.S. Cl. CPC G01R 31/374; H02J 7/00047

(57) ABSTRACT

Previously stored change-in-voltage-over-change-in-time characteristics of multiple rechargeable batteries are used to determine one of a plurality of types of rechargeable batteries that has been mounted to an automotive telematics system. And charging parameters and at least one state-of-health parameter for the rechargeable battery mounted to the automotive telematics system are automatically selected based on the determination of the type of rechargeable battery mounted the automotive telematics system.

### BACKGROUND

Rechargeable batteries have limited lifetime and eventually need to be replaced.

It is possible that a single product platform, such as for use in various automotive-telematics products, will work with more than one battery cell supplier with the same or different chemistry, but with slightly different charge/discharge parameters.

Such a battery-parameter difference may result in different charge profile, max/min voltage, Constant Current/Constant Voltage (CC/CV) threshold, and/or State-of-health algorithm.

Although it is known in the prior art to detect Nickel-metal hydride (NiMH) end of charge via a thermistor by using dT/dt (change in temperature vs time), such a technique is specific to NiMH chemistry and requires the system to reach full charge in order to see the temperature change which could be used to make a decision. dT/dt is used to detect charging fault (i.e., overcharge) but not to detect battery type.

Such a dT/dt method is apparently not helpful for distinguishing different subtypes of Lithium Ion (Li-Ion) batteries. Like for NiMH batteries, for Li_Ion batteries, dT/dt is used to detect charging fault (i.e., overcharge) and not to detect battery type.

A method that does not require fully charging the battery in order to detect battery type and that can be used within Li-ion chemistry or across multiple chemistries as long as the same voltage detection window can be set for all batteries in the group would advance the state of the art.

Further, the NiMH end of charge dV/dt method, which is specific to NiMH chemistry, is also only possible when battery reaches full charge. A method that does not require fully charging the battery in order to detect battery type would advance the state of the art.

Additionally, identifying the cells without relying on a unique physical/mechanical interface would advance the state of the art.

### BRIEF SUMMARY

Embodiments of the invention focus on voltage curve differences (change in voltage in time dv/dt) between rechargeable batteries from different manufacturers. In this way, use of several different types of batteries, without a need for additional mechanical identification or electrical circuits, is enabled. Embodiments of the invention rely on voltage-measurement functionality typically present in rechargeable battery circuits. Such functionality typically includes battery diagnostics that use voltage measurement and current measurement to establish battery state of health. Embodiments of the invention use functionality of this type to obtain voltage readings that are used, ultimately, for identifying a battery supplier or a battery type. In this way, additional hardware is not required for implementing embodiments of the invention.

### BRIEF DESCRIPTION OF THE DRAWINGS

FIG. 1 depicts a schematic block diagram of a system for identifying a battery supplier in accordance with embodiments of the invention.

FIG. 2 depicts selection of voltage-detection-window limits in accordance with embodiments of the invention.

FIG. 3 depicts an example of limit curves generated, in accordance with embodiments of the invention, based on known battery measurements.

FIG. 4 depicts top-voltage limit, bottom-voltage limit, upper-limit curve, and lower-limit curve, for battery supplier A, in accordance with embodiments of the invention.

FIG. 5 depicts top-voltage limit, bottom-voltage limit, upper-limit curves, and lower-limit curves for battery suppliers A, B, and C, respectively, in accordance with embodiments of the invention.

FIG. 6 depicts a method, in accordance with embodiments of the invention, for detecting the supplier of a rechargeable backup battery for an automotive telematics system.

### DETAILED DESCRIPTION

Embodiments of the invention are directed to detecting a supplier, from among a plurality of possible suppliers, of a particular rechargeable battery. Embodiments of the invention are discussed herein in the context of an automotive telematics platform for use in various automotive telematics products. But, as will be apparent to those skilled in the art, principles of the invention will also be applicable in other types of systems in which rechargeable batteries are used, such as mobile telephones and electric vehicles. Other examples are also possible.

In the past, telematics modules used a single supplier battery, and, therefore, detection of a rechargeable battery's characteristics was not required. Battery charge and state-of-health parameters where hard coded in such conventional systems.

Newer automotive telematics modules will typically work with more than one battery supplier and should, therefore, be able to automatically detect a battery supplier after the telematics modules have been deployed to the field, that is, used in an automobile on public roads, for example.

Existing telematics modules, which have already been deployed, may also use detection functionality of this type as the result of a software update.

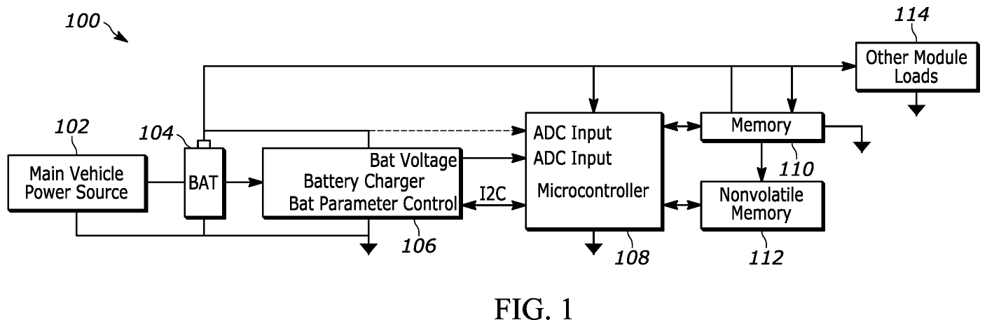

FIG. 1 depicts a schematic block diagram of a system for identifying a battery supplier in accordance with embodiments of the invention. The system 100 includes a main-vehicle power source 102, such as a conventional 12-volt lead-acid battery. Other types of batteries, including, but not limited to, 24-volt and 36-volt batteries, are also possible.

Backup battery 104 may be NiMH battery, a Lithium battery, or some any other suitable type of rechargeable battery for supplying an uninterrupted power supply to an automotive telematics system. The backup battery 104 may be a Lithium-Ion or Lithium-Ion Phosphate LiFePO4 single or multiple cell battery, which are available from: Murata, TWS, and EVE. Battery charger 106 charges the backup battery 104 and communicates battery voltage and battery-parameter-control information with a microcontroller 108. The battery charger may be an ASIC-like integrated circuit with a built-in state machine, constant current (CC) and constant voltage (CV) battery charger for single or multiple battery cells. Parameters for charging, performing SoH (State of Health), and diagnostics are written and read by the microcontroller 108 via the I2C bus. Suitable battery chargers are available from Analog Devices and Texas Instruments.

The microcontroller 108 may have analog-to-digital-converter (ADC) inputs and may exchange battery-parameter-control information with the battery charger 106 via Inter-Integrated Circuit (I2C), which is a two-wire serial protocol used to communicate between two devices or chips in an embedded system. I2C has two lines SCL and SDA, SCL is used for clock, and SDA is used for data.

The microcontroller 108 communicates with memory 110, nonvolatile memory 112, and other module loads 114. Other module loads are circuits that use energy provided by the battery which are not shown in FIG. 1. These could be a NAD (Network Access Device), Audio Power Amplifier, CAN (Controller Area Interface) bus interface. For simplicity, voltage regulators are not shown in FIG. 1. The microcontroller may be a single-core or multi-core microcontroller or microprocessor with internal or external memory with an I2C bus and ADC inputs. Suitable microcontrollers are available from NXP, Infineon, and Renesas.

Memory RAM (Random Access Memory) 110 may be Random Access Memory such as DDR3, DDR4, or LPDDR4 with bus width of 16 or 32 bits, used to execute microcontroller code. Size is dependent on the application, but can range from 128 MB to several GB and is available from Micron and Samsung.

Nonvolatile Memory 112 may be eMMC or raw NAND or NOR type FLASH memory used to save program code, data, and parameters. Size can vary from a few GB to 100s of GB. Suppliers include: Micron, Samsung, and Macronix.

In accordance with embodiments of the invention, design activities/system configuration include: identifying several battery sources and obtaining charge/discharge curves for each battery source.

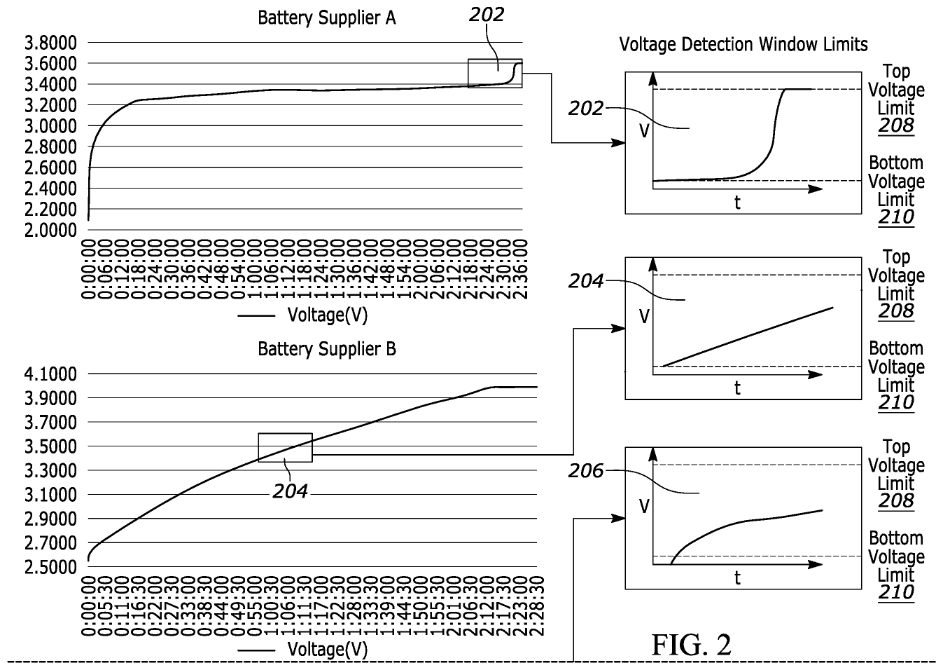

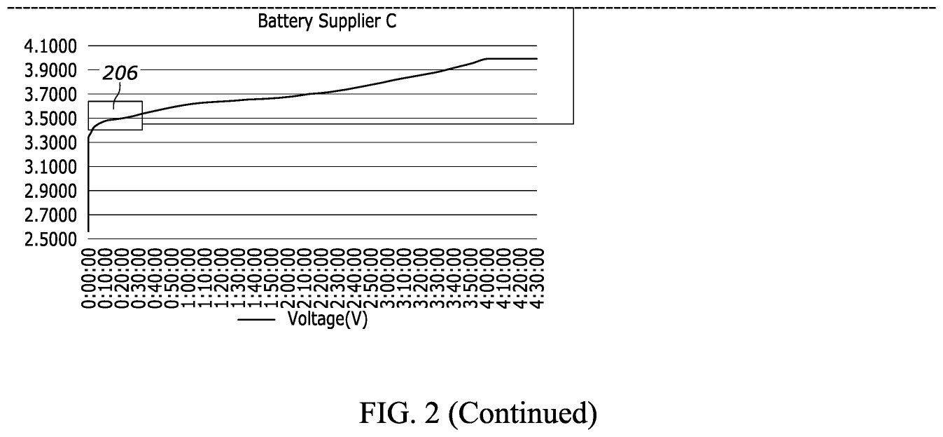

Identifying a minimum voltage window (also referred to as a detection voltage window) for each battery source based on the obtained charge/discharge curves such that the minimum voltage window/detection voltage window envelops a largest possible dv/dt across the battery sources. Detection voltage windows are discussed in more detail below with reference to FIG. 2.

Identifying datapoints (voltage vs time) to be saved in a vehicle's microcontroller unit (MCU) non-volatile memory (NVM) to be used by the detection algorithm during battery detection.

FIG. 2 depicts selection of voltage-detection-window limits in accordance with embodiments of the invention. On the left-hand side of FIG. 2, voltage-versus-time information for batteries from multiple suppliers, battery suppliers A, B, and C, is shown. Voltage-detection windows 202, 204, and 206 are selected such that the voltage window envelops a largest possible dv/dt across the battery suppliers A, B, and C. In the example of FIG. 2, for battery supplier A, the voltage-detection window 202 has a bottom voltage limit 210 of approximately 3.4 and a top voltage limit 208 of approximately 3.6. The same values, namely approximately 3.4 and 3.6, are also selected, as shown in FIG. 2, for the bottom and top voltage limits for the voltage-detection windows 204 and 206 of battery suppliers B and C.

The top-voltage limit 208 and the bottom-voltage limit 210 are the same for voltage-detection windows 202, 204, and 206. But the times during which those voltages occur while charging batteries from suppliers A, B, and C differ. In the example of FIG. 2, voltage-detection window 202 spans 2:24:00 through 2:36:00, voltage-detection window 204 spans approximately 1:00:30 through 1:17:00, and voltage-detection window 206 spans approximately from 0:00:00 through 0:30:00. These time values are presented in the format of hours:minutes:seconds of charging time.

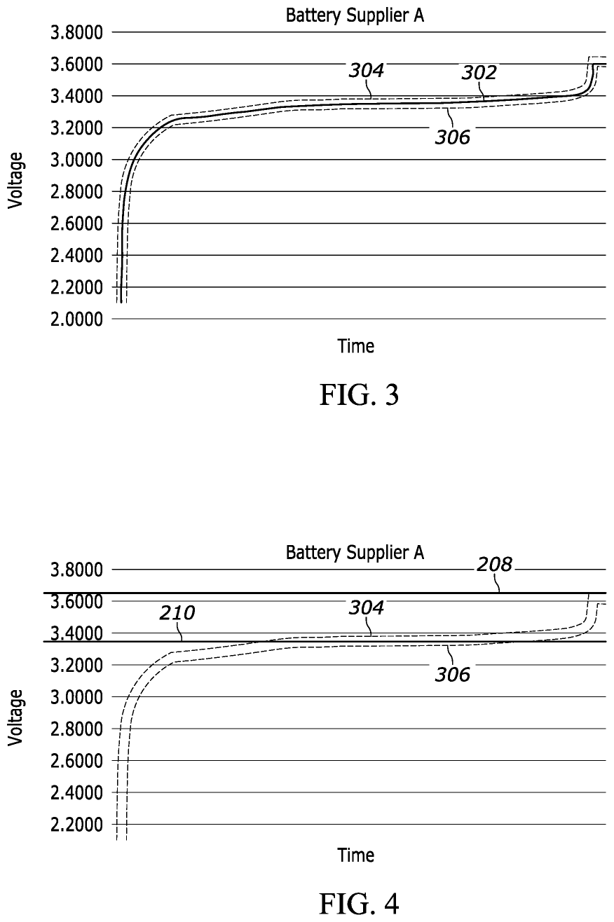

FIG. 3 depicts an example of limit curves generated, in accordance with embodiments of the invention, based on known battery measurements. The solid line plot 302 represents battery data obtained during a battery-characterization process. Line 302 may be either a measured data average over several samples, or it could be obtained from the supplier. In both cases, data is obtained via measurement.

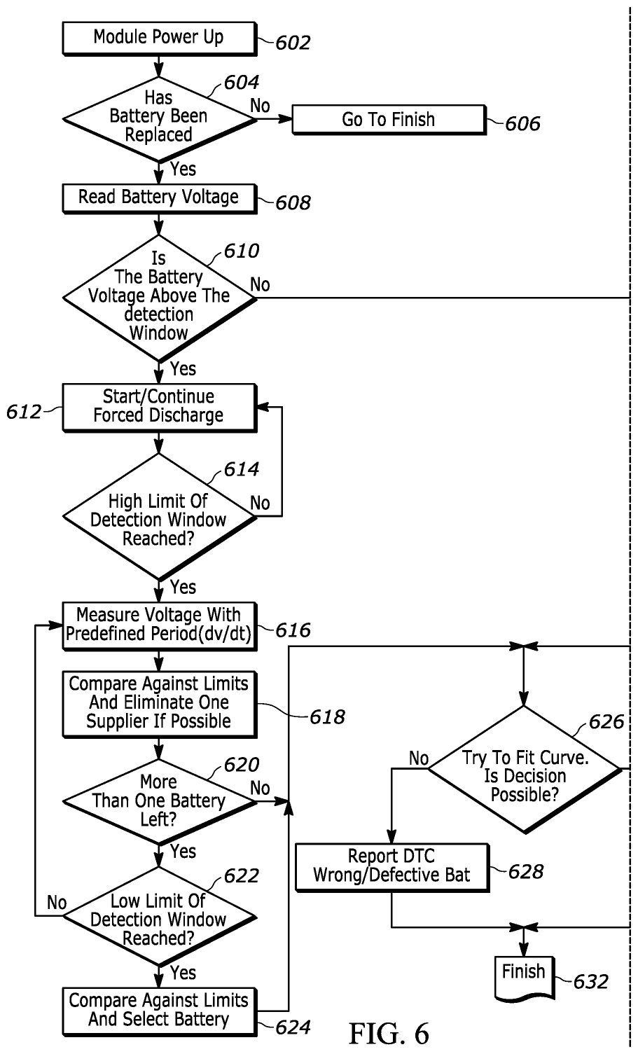

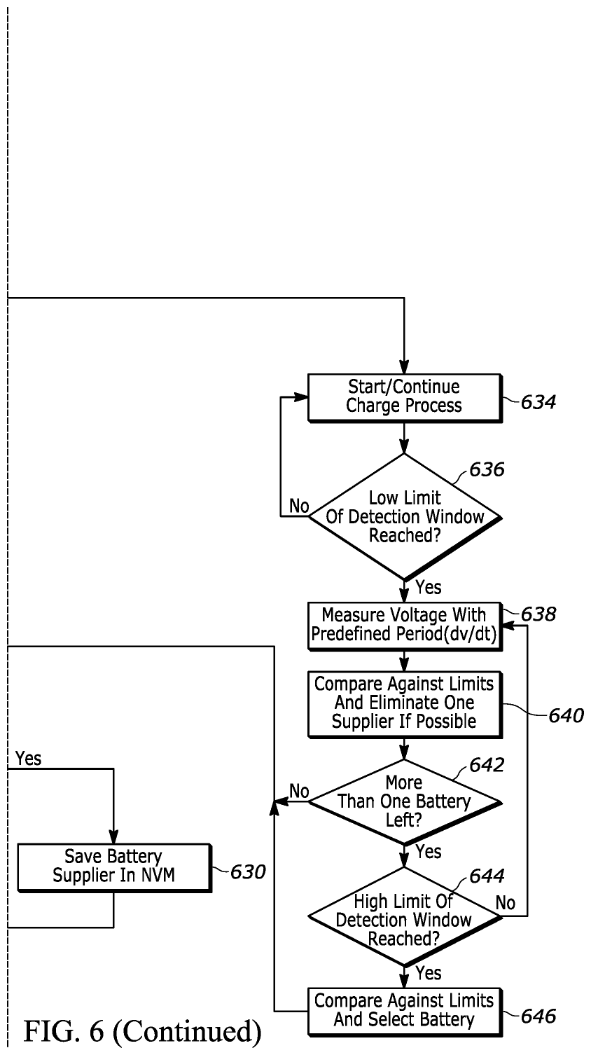

Upper-limit curve 304 and lower-limit curve 306 are generated such that they envelop tolerances that apply to the pertinent battery supplier, which, in the example of FIG. 3, is battery supplier A. The limit curves may be obtained based on measured data across a predefined temperature range. A relatively wider temperature range will cause these limits to get wider, and, at a certain point, the overlap between limits form other battery types will be too large. Embodiments of the invention are, therefore, limited to a certain temperature range, which is likely to be encountered while the detection algorithm of FIG. 6 is performed under normal operating conditions of during powerup of a vehicle's telematics system.

FIG. 4 depicts top-voltage limit 208, bottom-voltage limit 210, upper-limit curve 304, and lower-limit curve 306, for battery supplier A, in accordance with embodiments of the invention. As mentioned above, the top-voltage limit 208 and the bottom-voltage limit 210 define a common voltage-detection window 202, 204, and 206 for batteries from multiple battery suppliers. In the example shown in FIG. 2, the top-voltage limit is approximately 3.6 volts, and the bottom-voltage limit is approximately 3.4 volts.

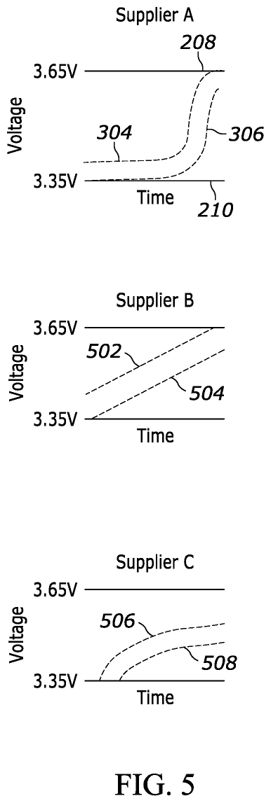

FIG. 5 depicts top-voltage limit 208, bottom-voltage limit 210, upper-limit curves 304, 502, and 506 and lower-limit curves 306, 504, and 508 for battery suppliers A, B, and C, respectively, in accordance with embodiments of the invention. Unlike the top-voltage limit the bottom-voltage limit, however, the upper-limit curve 304 and the lower-limit curve 306 are specific to particular battery suppliers. Stated differently, the upper-limit curve 304 and the lower-limit curve 306 for a battery from supplier A, in the example of FIGS. 2-5, differ from the upper-limit curves 502 and 506 and the lower-limit curves 504 and 508 of batteries from the other battery suppliers, battery suppliers B and C, respectively.

As mentioned above, and in accordance with embodiments of the invention and the example of FIGS. 2-5, the top-voltage limit 208 and the bottom-voltage limit 210 are selected such that voltage-detection windows 202, 204, and 206 envelops a largest possible dv/dt across the battery suppliers A, B, and C. Further, voltage-detection windows 202, 204, and 206 are selected to in order to maximize the deviations between the respective upper-limit curves 304, 502, and 506 and the respective lower-limit curves 306, 504, and 508 in order to facilitate detection of battery suppliers by making the detection windows 202, 204, and 206 as distinctive with respect to one another as is possible. Further, voltage-detection windows 202, 204, and 206 should be selected within the constant current (CC) charge mode, and charge current should be the same for the batteries from the various battery suppliers.

Points along the upper-limit curve and the lower-limit curve for each voltage-detection window are stored in non-volatile memory 112 for use during the detection phase, which is discussed in more detail below with reference to FIG. 6. Stated differently, points along the upper-limit curve 304 and the lower-limit curve 306 for the voltage-detection window 202 for battery supplier A are stored in non-volatile memory. Similarly, points along the upper-limit curve 502 and the lower-limit curve 504 for the voltage-detection window 204 for battery supplier B are stored in non-volatile memory. And points along the upper-limit curve 506 and the lower-limit curve 508 for the voltage-detection window 206 for battery supplier C are stored in non-volatile memory.

FIG. 6 depicts a method, in accordance with embodiments of the invention, for detecting the supplier of a rechargeable backup battery for an automotive telematics system. Steps of the method include: module power up 602; detecting whether the battery has been replaced 604; if yes, the battery voltage is read 608; decide if charge or discharge is needed based on the battery voltage to get to the detection voltage window 610.

With respect to determining whether the battery has been replaced, as shown at 604, once battery state-of-health (SoH) algorithm detects battery end of life, it will save this information in the non-volatile memory 112 along with battery SoH algorithm results, and a diagnostic trouble code (DTC) is set. As is known in the art, Battery SoH algorithms measure the remaining lifetime of a battery based on measurement of the internal battery resistance, which is done by measuring voltage at various current loads. SoH calculates the internal battery resistance, which is compared to a limit above which the battery is deemed to be not useable.

On every power up of the automobile telematics system, direct current (DC) resistance of the backup battery 104 is measured. DC resistance of an aged battery is higher than DC resistance of a new battery. So, a decrease in the measured DC resistance relative to previous measurements indicates that the battery has been replaced. And a service technician may indicate via a diagnostics tool that the battery has been replaced.

At 610, a determination is made with respect to whether the battery voltage is above or below the voltage detection window 202, 204, 206.

When the battery voltage is above the voltage detection window, the yes branch from 610 is followed, and a forced discharge of the battery is started or continued as shown at 612. Such a forced discharge may be performed by using a specialized electronic circuit capable of dissipating battery energy in to heat via a resistor.

Once the upper limit 208 of the voltage detection window is reached, the voltage/time measurements are periodically taken 616 and saved in NVM 112. This can occur during charge or forced discharge. Measurements can be taken during normal operation discharge from the battery 104, if the battery does not need to be fully charged before use.

The periodically measured voltages are compared at 618 against the limit-point curves 304 and 306, 502 and 504, and 506 and 508, and a battery-supplier is eliminated if the periodically measured voltages are outside the limit-point curves for a particular battery supplier. The measured points will track inside of Supplier A, B, or C limits, as long as a battery from one of these suppliers is installed in the system.

While multiple battery suppliers have not yet been eliminated, the yes branch from 620 is followed and a determination is made 622 with respect to whether the lower limit 210 of the voltage detection window 202, 204, 206 has been reached. If not, the no branch 622 is followed back to 616. If so, the yes branch 622 is followed, and the periodic measurements are compared to the limit-point curves 304 and 306, 502, and 504, and 506 and 508 to select a battery supplier 624 based on a best fit between the periodic measurements and the limit-point curves for the battery suppliers that have not already been eliminated at step 618. Best fit could be done on point-by-point basis. For example: measurement is done, and compared to limits and a pass/fail determination is recorded for each supplier based on the corresponding limits. Then the supplier with the highest number of passed measurements is picked. Since limits for suppliers are known, the algorithm can potentially rule out certain suppliers before it finishes. This can be done based on exceeding a predetermined number of failed measurements, such as, for example, more than 10%, or 20%, or 30% of the measurements.

When the no branch from 610 is followed, steps 634-646 are performed and are similar steps 612-624, except that steps 634-646 are directed to taking periodic measurements of increasing voltages, while steps 612-624 are directed to taking periodic measurements of decreasing voltages.

At 626, an attempt is made to find a best fit between the periodic measurements and the limit-point curves for the one or more battery suppliers that have not already been eliminated at steps 620 or 642. Once measurements have been taken, then the amount of passed/failed measurements for each supplier may be compared with one another, and the supplier with the highest number of passing measurements may be selected as a best fit.

Once the opposite limit of the voltage detection window is reached, the curve obtained by taking periodic measurements is compared to the predefined data 208 and 210, 502 and 504, and 506 and 508 created during system configuration and, when a battery-supplier selection, based on a best fit between the periodic measurements and the predefined data is possible, the yes branch from 626 is followed, and battery parameters are saved in NVM 112, as shown at 630. When such a battery-supplier selection is not possible, the no branch from 626 is followed to 628 where a DTC is activated indicating that a wrong or defective battery has been installed. Processing finishes at 632.

In addition to the “best fit” technique described above, other ways are also possible. There is a whole math theory devoted to curve fitting with different algorithms such as Regression Curve fitting, Least Squares, or Gauss_Newton, and the like.

The least squares method would use one curve, such as 302 for Battery Supplier A, and no limit curves 304 and 306. Then the algorithm would sum the squares of the difference of each measurement versus the curve 302 for each time slice. This may be done for each supplier curve. Then the supplier curve with the lowest result (lowest error) may be selected. Unlike the “best fit,” this approach involves all points to be taken before the decision can be made.

Advantageously, embodiments of the invention do not require any hardware changes and, instead, rely upon the existing electronic circuitry (voltage measuring ADC), and the techniques for identifying a battery supplier presented herein. Although the algorithm is presented in the context of a software implementation, those skilled in the art will realize that other implementations through any suitable combination of hardware and/or software are possible.

While the automotive telematics system is deployed it will periodically measure battery parameters to establish the remaining battery life. Once end of battery life is determined to be imminent, a DTC (Diagnostic Trouble Code) will be set. A vehicle operator may then bring the vehicle with the DTC to an authorized service center for replacement of the rechargeable backup battery.

The method described in this disclosure allows the authorized service center to carry more than one supplier which was previously approved by the telematics-system supplier without a need to keep track of which backup battery is being installed.

This method also allows the authorized service center to replace the battery without a need of running any diagnostics. The battery-supplier-identification algorithm automatically starts on the next telematics-system power up and will continue with the diagnostics until a determination regarding battery-supplier identification is reached.

As mentioned above with reference to FIG. 6, if a battery, which significantly differs from any of those which were preprogrammed by the telematics-system supplier is installed, then the algorithm will not converge, and another DTC will be set prompting the vehicle operator to return to the service center.

This disclosure also covers usage in non-safety-related devices which can start using a battery upon being installed. In such a case, the algorithm will conduct diagnostics during normal use.

This method of detecting a battery supplier offers a high level of accuracy because it is based on 100s, or even 1000s, of datapoints taken over time which are then compared to a lookup table containing an envelope (min/max limits) spaced over time.

As compared to using a single threshold,

Curve fitting is much more accurate and opens up the possibility for statistical decisions (e.g., at least 75%, 80%, 85%, or 90% of points being within predefined limits can be presumed to be “close enough” for a positive decision). With one point/threshold there is only a yes/no decision.

Once a determination has been made regarding which type of battery has been mounted, charging parameters and parameters for determining battery state-of-health/useful remaining life of the battery are set based on the determination regarding which type of battery has been mounted. The parameters for determining battery state-of-health/useful remaining life of the battery may include: minimum and maximum battery voltage (V), capacity (Ah), maximum charge current (A), and internal battery resistance (Ohm).

The following table sets forth a list of example charging parameters and an example state-of-health parameter and how the values of these parameters differ between battery suppliers, in accordance with embodiments of the invention. Other such examples are also possible.

| | Unit | Supplier A | Supplier B | Supplier C |
|---|---|---|---|---|
| Charge Voltage | V | 3.65 | 4.1 | 4.2 |
| (max Voltage) | | | | |
| Discharge Cut-off | V | 2 | 2.5 | 2.75 |
| (min Voltage) | | | | |
| Min Charge Temperature | deg C. | 0 | −20 | 0 |
| Max Charge Temperature | deg C. | 60 | 50 | 60 |
| Min Discharge Temperature | deg C. | −20 | −40 | −40 |
| Max Discharge Temperature | deg C. | 60 | 85 | 85 |
| Max Charge Current | mA | 325 | 200 | 400 |
| Max Internal resistance | mOhm | 70 | 70 | 150 |
| @25 C. | | | | |

In accordance with embodiments of the invention, a SoH algorithm may be performed as follows: each battery has a model (3rd order polynomial) of its internal battery resistance versus temperature. The microcontroller uses this model and a sensed battery temperature to calculate a maximum-allowable-internal-resistance limit of the battery at a current temperature. The battery microcontroller also computes an internal resistance of the battery by measuring several voltage measurements at different electrical current levels and applying ohms law to find resistance. This calculated internal battery resistance is then compared against the calculated maximum-allowable-internal-resistance limit, and if the calculated internal battery resistance is higher than the calculated maximum-allowable-internal-resistance limit, then the battery is deemed to be unusable and replacement is, therefore, recommended.

A diagnostic trouble code can be provided when battery replacement is recommended based on the battery state-of-health parameters, which, in turn, were chosen based on the determined type of mounted battery.

In addition to and/or instead of setting a DTC, haptic feedback through a steering wheel, driver's seat, and/or accelerator pedal may be used to notify a driver when the battery needs to be replaced. Further, an autonomous, vehicle may drive itself, by controlling steering, braking, speed, and acceleration) to the authorized automotive-repair facility to have the re-chargeable battery replaced upon a determination of impending end-of-life of the rechargeable automotive-telematics-system backup battery.

It should be understood that any of the devices described herein (e.g., the microcontroller, the battery charger, any presentation or display devices, and the external devices) may use a computing device to implement various functionality and operation of these devices. In terms of hardware architecture, such a computing device can include but is not limited to a processor, a memory, and one or more input and/or output (I/O) device interface(s) that are communicatively coupled via a local interface. The local interface can include, for example but not limited to, one or more buses and/or other wired or wireless connections. The processor may be a hardware device for executing software, particularly software stored in memory. The processor can be a custom made or commercially available processor, a central processing unit (CPU), an auxiliary processor among several processors associated with the computing device, a semiconductor based microprocessor (in the form of a microchip or chip set) or generally any device for executing software instructions.

The memory devices described herein can include any one or combination of volatile memory elements (e.g., random access memory (RAM), such as dynamic RAM (DRAM), static RAM (SRAM), synchronous dynamic RAM (SDRAM), video RAM (VRAM), and so forth)) and/or nonvolatile memory elements (e.g., read only memory (ROM), hard drive, tape, CD-ROM, and so forth). Moreover, the memory may incorporate electronic, magnetic, optical, and/or other types of storage media. The memory can also have a distributed architecture, where various components are situated remotely from one another, but can be accessed by the processor.

The software in any of the memory devices described herein may include one or more separate programs, each of which includes an ordered listing of executable instructions for implementing the functions described herein. When constructed as a source program, the program is translated via a compiler, assembler, interpreter, or the like, which may or may not be included within the memory.

It will be appreciated that any of the approaches described herein can be implemented at least in part as computer instructions stored on a computer media (e.g., a computer memory as described above) and these instructions can be executed on a processing device such as a microprocessor. However, these approaches can be implemented as any combination of electronic hardware and/or software.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. The invention in its broader aspects is therefore not limited to the specific details, representative apparatus and method, and illustrative example shown and described. Accordingly, departures may be made from such details without departing from the spirit or scope of applicant's general inventive concept.

1. A method, comprising:
using previously stored change-in-voltage-over-change-in-time characteristics of a plurality of rechargeable batteries to determine one of a plurality of types of rechargeable batteries that has been mounted to an automotive telematics system;
automatically selecting charging parameters and at least one state-of-health parameter for the rechargeable battery mounted to the automotive telematics system based on the determination of the type of rechargeable battery mounted to the automotive telematics system.

2. The method of claim 1, wherein fully charging the rechargeable battery mounted to the automotive telematics system is not needed in order to determine the type of the rechargeable battery.

3. The method of claim 1, wherein the plurality of types of rechargeable batteries comprises batteries from a respective plurality of rechargeable-battery suppliers.

4. The method of claim 1, wherein the plurality of types of rechargeable batteries comprises batteries from a respective plurality of different rechargeable-battery chemistries.

5. The method of claim 1, wherein the determination of the type of the rechargeable battery comprises determining a best fit between measured voltage-versus-time values within a common voltage-detection window that has a bottom-voltage limit and a top-voltage limit that are both the same for the plurality of types of rechargeable batteries.

6. The method of claim 5, wherein the bottom-voltage limit and the top-voltage limit of the common voltage-detection window are selected such that a plurality of voltage-versus-time characteristics of the corresponding types of rechargeable batteries differ as much as possible with respect to one another.

7. The method of claim 6, wherein each of the plurality of voltage-versus-time characteristics of the corresponding types of rechargeable batteries are represented with a respective one of a plurality of pairs of a respective upper-limit-point curve and a respective lower-limit-point curve.

8. The method of claim 7, wherein determining the best fit between measured voltage-versus-time values within the common voltage-detection window further comprises: comparing a measured voltage of the rechargeable battery mounted to the automotive telematics system with the plurality of pairs of the respective upper-limit-point curve and the respective lower-limit-point curve within the common voltage-detection window for each of the respective types of rechargeable batteries.

9. The method of claim 1, wherein the automatically selected charging parameters and the at least one state-of-health parameter include at least two of: maximum charge voltage, minimum discharge cut-off voltage, minimum charge temperature, maximum charge temperature, minimum discharge temperature, maximum discharge temperature, maximum charge current, and maximum internal resistance at 25 degrees Celsius.

10. An apparatus, comprising:
a rechargeable battery;
a battery-charger coupled to the rechargeable battery;
a microcontroller coupled to the rechargeable battery and to the rechargeable battery, wherein the microcontroller is configured to perform operations including:
using previously stored change-in-voltage-over-change-in-time characteristics of a plurality of rechargeable batteries to determine one of a plurality of types of rechargeable batteries that has been mounted to an automotive telematics system; and
automatically selecting charging parameters and state-of-health parameters for the rechargeable battery mounted to the automotive telematics system based on the determination of the type of rechargeable battery mounted to the automotive telematics system.

11. The apparatus of claim 10, wherein fully charging the rechargeable battery is not needed in order to determine the type of the rechargeable battery.

12. The apparatus of claim 10, wherein the plurality of types of rechargeable batteries comprises batteries from a respective plurality of rechargeable-battery suppliers.

13. The apparatus of claim 10, wherein the plurality of types of rechargeable batteries comprises batteries from a respective plurality of different rechargeable-battery chemistries.

14. The apparatus of claim 10, wherein the determination of the type of the rechargeable battery comprises determining a best fit between measured voltage-versus-time values within a common voltage-detection window that has a bottom-voltage limit and a top-voltage limit that are both the same for the plurality of types of rechargeable batteries.

15. The apparatus of claim 14, wherein the bottom-voltage limit and the top-voltage limit of the common voltage-detection window are selected such that a plurality of voltage-versus-time characteristics of the corresponding types of rechargeable batteries differ as much as possible with respect to one another.

16. The apparatus of claim 15, wherein each of the plurality of voltage-versus-time characteristics of the corresponding types of rechargeable batteries are represented with a respective one of a plurality of pairs of a respective upper-limit-point curve and a respective lower-limit-point curve.

17. The apparatus of claim 16, wherein determining the best fit between measured voltage-versus-time values within the common voltage-detection window further comprises: comparing a measured voltage of the rechargeable battery with the plurality of pairs of the respective upper-limit-point curve and the respective lower-limit-point curve within the common voltage-detection window for each of the respective types of rechargeable batteries.

18. The apparatus of claim 10, wherein the rechargeable battery is mounted to an automotive telematics system.

19. The apparatus of claim 10, wherein the automatically selected charging parameters and the at least one state-of-health parameter include at least two of: maximum charge voltage, minimum discharge cut-off voltage, minimum charge temperature, maximum charge temperature, minimum discharge temperature, maximum discharge temperature, maximum charge current, and maximum internal resistance at 25 degrees Celsius.
